(19) United States
(12) Patent Application Publication
(10) Pub. No.: US 2013/0063889 A1
(43) Pub. Date: Mar. 14, 2013

(54) System and Method for Cooling Notebook Computer Surface

(71) Applicants: Clinton Yee, Corona, CA (US); Spencer Yee, Los Angeles, CA (US)

(72) Inventors: Clinton Yee, Corona, CA (US); Spencer Yee, Los Angeles, CA (US)

(21) Appl. No.: 13/609,160

(22) Filed: Sep. 10, 2012

Related U.S. Application Data
(60) Provisional application No. 61/533,569, filed on Sep. 12, 2011.

(51) Int. Cl. G06F 1/20; H05K 7/20; B23P 19/04; H05K 5/02

(52) U.S. Cl. 361/679.48; 361/679.46; 312/223.2; 29/428

(57) ABSTRACT

A system and method for cooling the underside surface of a portable computer device having a casing and at least one connector for releasable engagement with a portable computer device. The casing has an upper surface, a lower surface and space therebetween whereby so that the lower surface of the portable computer device is adjacent to the upper surface of the system casing. The system may also include a fan.

This application claims the benefit of provisional patent application No. 61/533569 entitled “Cooling and Securing Device for Notebook Computers” filed on Sep. 12, 2011, the entirety of which is hereby incorporated by reference.

### FIELD OF INVENTION

The embodiments described herein relate to systems for managing the thermal envelope surrounding an electronic device. More particularly, the embodiments described herein thermally manage the underside surface of a laptop or notebook computer.

### DRAWINGS

FIG. 1 is a perspective view of a first embodiment of the invention.

FIG. 2 is a perspective view of FIG. 1 with the top cover body of the device removed to expose to components inside (FIG. 1.)

FIG. 3 depicts a perspective view of an exemplary personal computing device (notebook computer) attached to the first embodiment of FIG. 1.

FIG. 4 is a cross-sectional side view of FIG. 3.

FIG. 5 depicts the magnified area A of FIG. 4.

FIG. 6 depicts the magnified area B of FIG. 4.

FIG. 7 is a perspective view of the embodiment of FIG. 3 with a tripod receiving recess .

FIG. 8 is a perspective view of FIG. 7 with a tripod attached thereto.

FIG. 9 is a perspective view of a second embodiment of the invention.

FIG. 10 is an exploded view of FIG. 9.

FIG. 11 is a perspective view of a third embodiment of the invention.

### DETAILED DESCRIPTION

Personal portable computers, such as notebook or laptop computers often generate excessive heat while they are being used. Because of their light weight and easy portability, users often place these devices in their laps during use. The user's clothing or surrounding materials such as a pillow or bedding, causes the ventilation system within a computer to become ineffective because the clothing or bedding blocks the vents and prevents air discharge from the device. This may result in a system crash or decreased performance because of the device's inability to effectively ventilate the heat created during use.

In addition, the heat can cause severe discomfort to the user when these devices are touched or held on the lap for any extended period. Overheating in portable computers and similar devices increases the risk of the user getting burned when placing these devices on the lap. For these reasons, the embodiments of the present invention provide for an effective system for creating a surface that can be placed on a user's lap that allows a portable computer to effectively ventilate while providing a comfortable surface for the user to contact.

There are a number of existing systems directed at cooling the portable computer itself In addition there are a few systems that provide a barrier between the portable computer and the user. However, these devices are bulky and do not allow users to fixedly attach the portable computer to the barrier device. Accordingly, they limit the portability of the portable computer. The embodiments of the present invention provide protection from excessive heat while increasing mobility and usability of the portable computer.

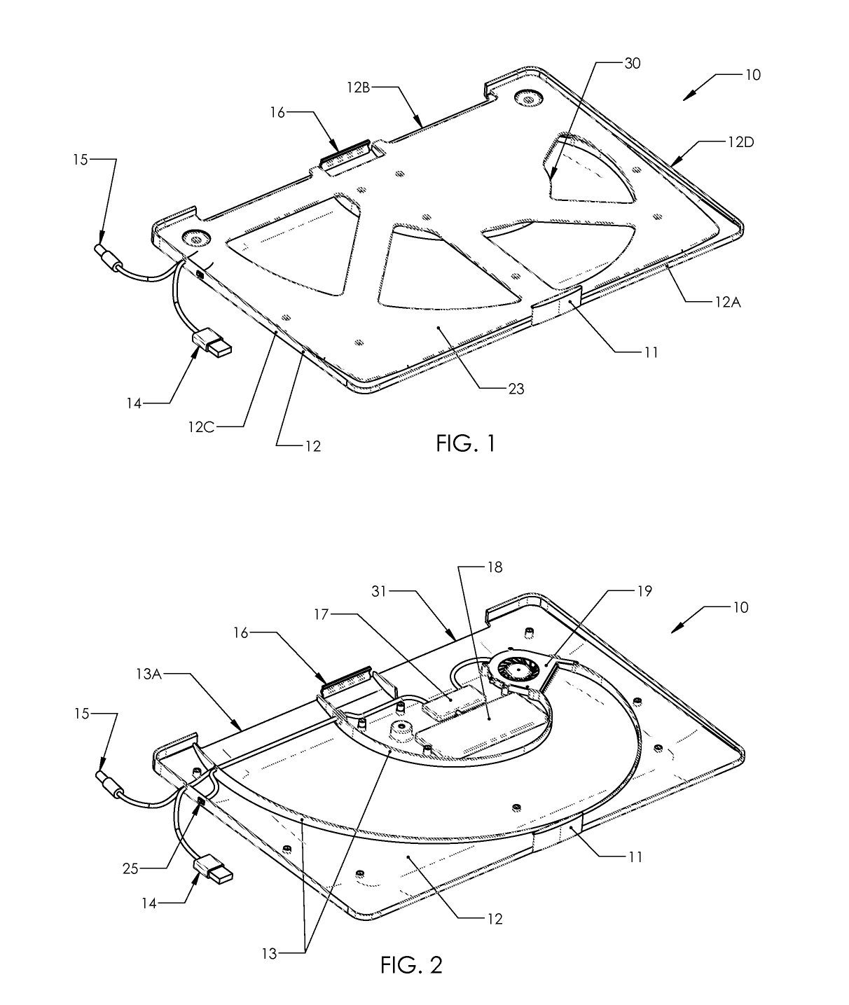

The first embodiment 10 of the present invention is shown generally in FIG. 1. The first embodiment 10 includes a casing 12 made of a rigid material such as a plastic or metal or wood. The casing may be shaped to accommodate different shaped portable devices. The casing has front, rear, left and right sides (12A, 12B, 12C and 12D respectively). A front latch 11 extends upwardly from the casing 12 at a point, preferable in the middle, on the front side 12A of the casing 12. Similarly there is a rear latch 16 located at a point on the rear side 12B of the casing 12. The front 11 and rear latches 16 are designed to connect the first embodiment 10 to the portable computer or other device.

FIG. 1 also shows a top cover 23 that extends across some or all of the surface of the casing 12. As shown in FIG. 1, the top cover 23 has vents 30. The vents 30 are designed to be adjacent to the lower surface of a portable computer or other device (not shown in FIG. 1). FIG. 1 also shows a charging plug 15 for attaching to a power source to power the first embodiment 10. In addition, the first embodiment 10 has a USB power plug 14 to alternatively attach to a power source to power the first embodiment 10. These functions will be explained in detail below.

FIG. 2 shows the first embodiment 10 with the top cover 23 removed. This reveals the powered cooling system which includes an electric fan 19, a battery 18 and a power controller 17. The fan 19 is connected to an air flow guide 13 which directs the propelled air from the fan to an air flow guide outlet 13A. Air flow opening 31 is located along the rear side 12B of the casing 12 on the opposed side of the rear latch 16. Air flow opening 31 helps to vent the air from within the casing 12 volume externally even when the fan 19 is not operating. When the fan is operating, the air flow opening 31 serves to draw cool external air through the opening from and into the space between the casing 12 and the top cover 23.

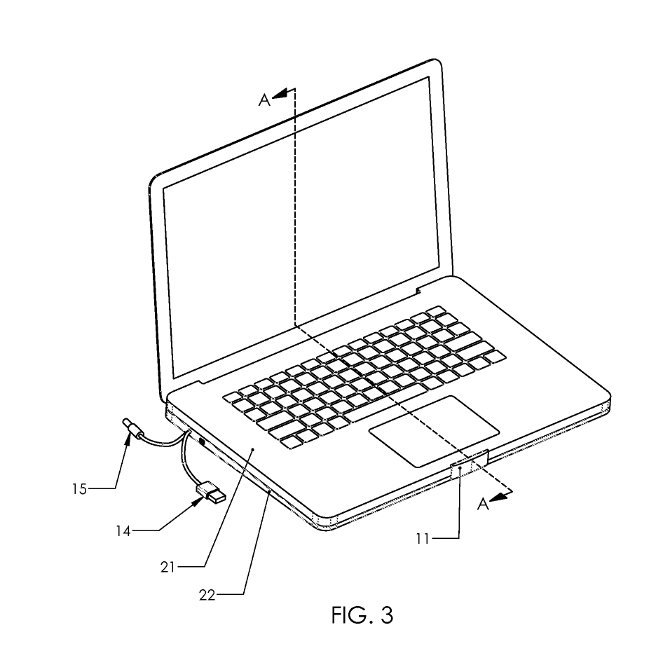

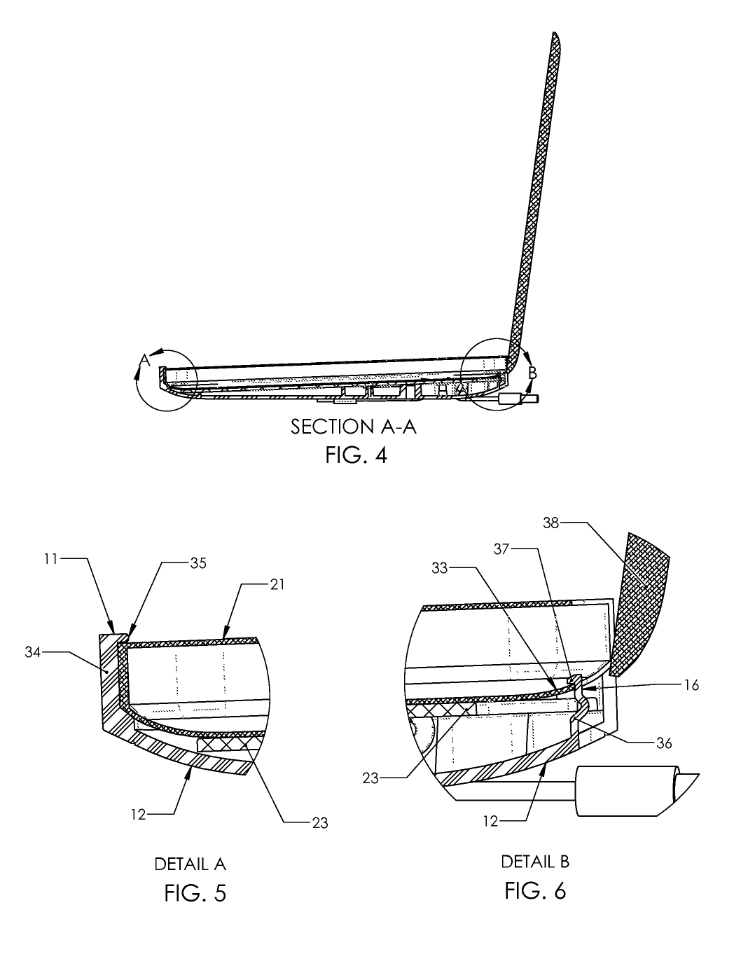

FIG. 3 illustrates an exemplary portable computer device 32 attached to the first embodiment 10. The lower surface 33 (shown in FIG. 4) of the computer device 32 is received onto the top cover 23 of the first embodiment 10. The front 11 and rear latches 16 extend upwardly to removeably attach the body of the computer device 32 thereto. The portable computer device 32 has an upper screen portion 38 and a lower keyboard portion 39. The upper screen portion 38 is typically hinged to the lower keyboard portion so that when the device 32 is not in use, the user may close the upper portion 38 down upon the lower portion 39 for storage and transport. As shown in FIGS. 4 and 5, the front latch 11 includes an upwardly extending member 34 and a lip 35. The lip 35 engages a front portion of the computer device 32 and holds the device adjacent to the casing, as shown in detail in FIG. 5. Similarly, the rear latch 16 includes rear protruding member 36. The rear protruding member 36 is tortuous in cross section. This is designed to accommodate the top cover 23 of the first embodiment 10 without resulting in a larger device than is necessary. As seen in FIG. 6, the rear protruding member extends upwardly beyond the lower surface 33 of the portable computer device 32. A rear lip projects horizontally forward to engage with the lower surface 33 of the computer device 32. The rear latch 16 engages with the computer device 32 in a manner so as to enable the hinged upper portion 38 of the computer device to move freely without interference from the rear latch.

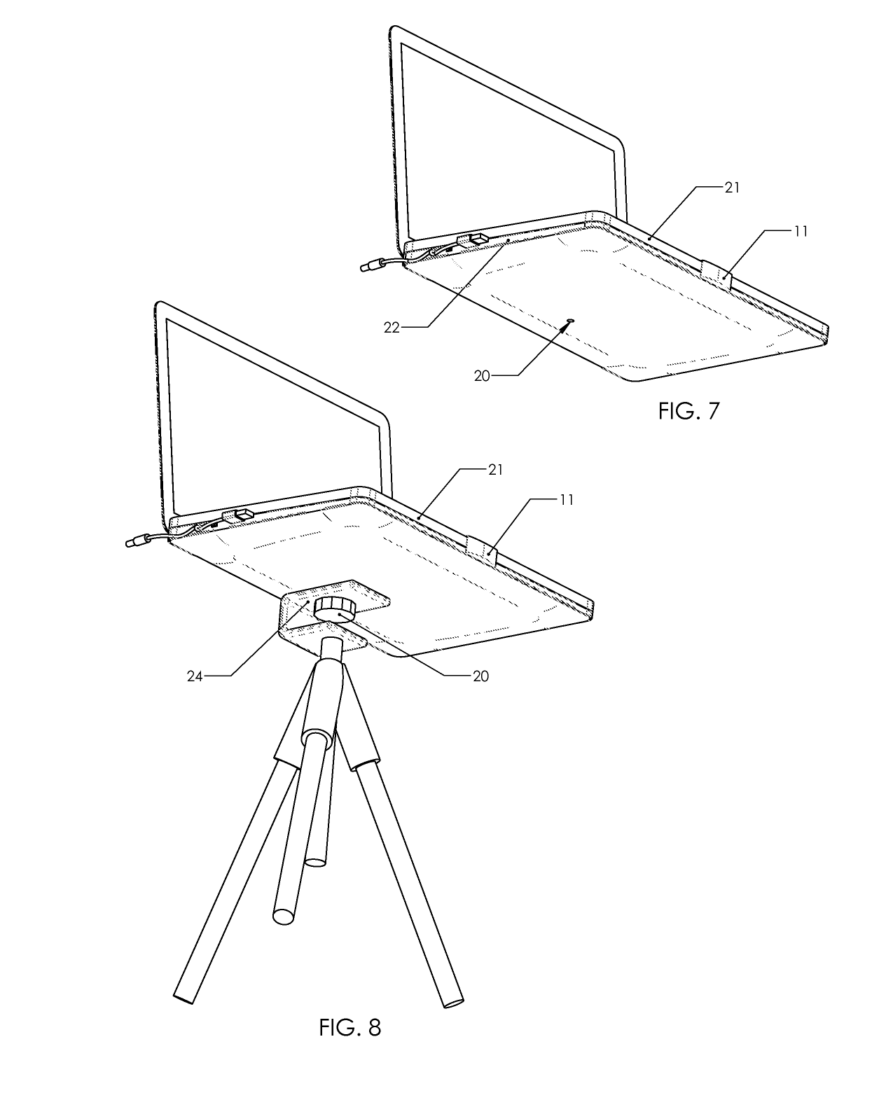

FIG. 7 shows an optional feature of the first embodiment 10 in the form of a tripod screw mount 20 in the lower surface of the casing 12. The tripod screw mount 20 receives a tripod assembly 24 shown in FIG. 8.

To use, the user first attaches the first embodiment 10 to a portable computing device 32. This is achieved by ensuring that the lip 35 of the front latch 11 contacts the upper surface of the portable computer device 21, as shown in FIG. 5. This results in the forward portion of the portable computer device 21 to be received into the lip 35 and rest upon the top cover 23. Similarly, the user attaches the rear lip 37 of the rear latch 16 onto a recessed portion of the portable computing device. This results in the rear lip 37 pulling the lower surface of the portable computer device 21 downward so that it rests upon the top cover 23. Once assembled, the space created within the first embodiment 10 between the top cover 23 and the casing 12 creates an air pocket which insulates the heat created in the portable computer device 32 from the user's lap when the first embodiment 10 is attached to the portable computer device 32. To create further cooling, the user may choose to operate the fan 19. This is accomplished by a switch 25 or the like located on the side of the casing. The fan may be automatically switched on and its speed varied as programmed by the power controller 17.

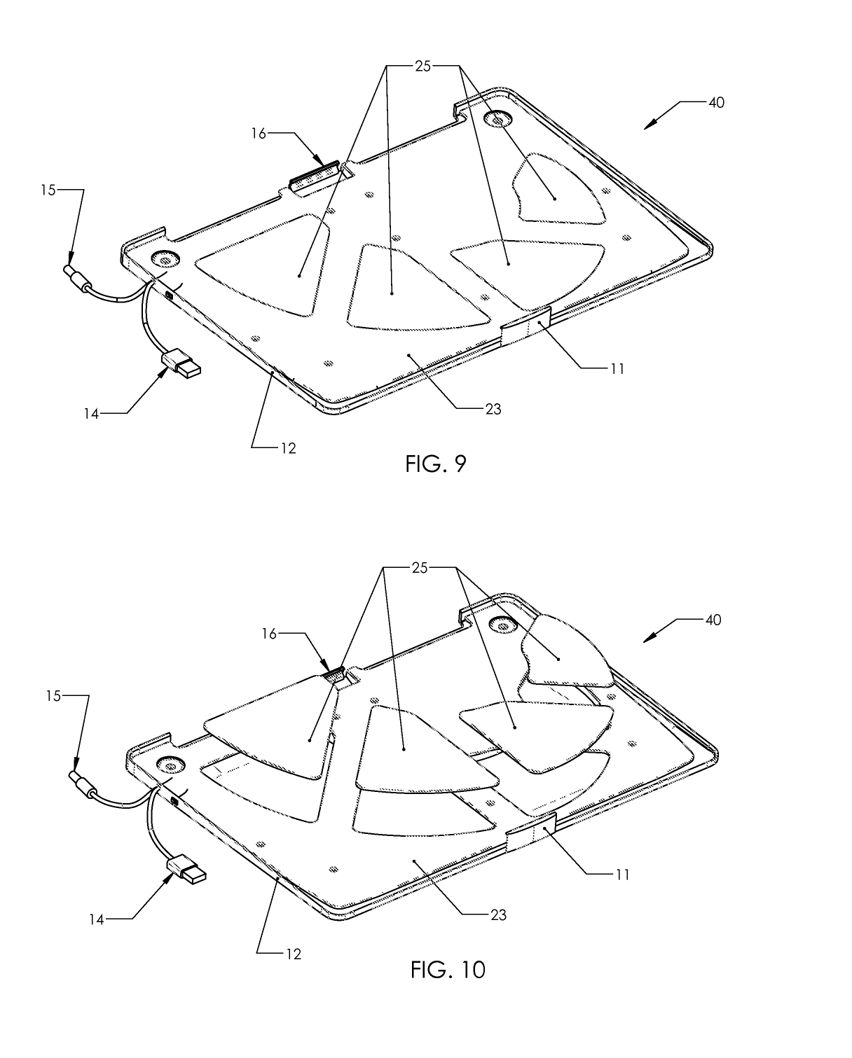

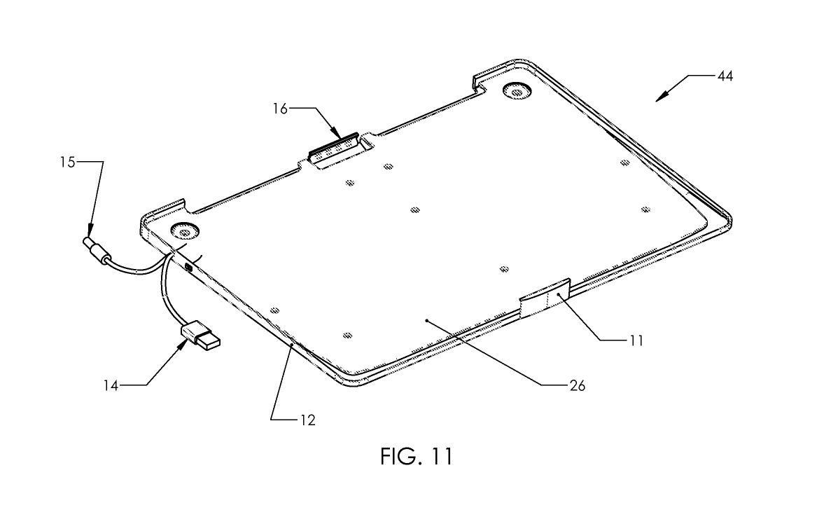

A second embodiment 40 is shown in FIG. 9. All items similarly structured are represented by similarly numbered items as described above. The second embodiment 40 includes vent plugs 42. The vent plugs 42 may be removeable pieces as shown in FIG. 10 where each piece is placed within the vent 30 openings in the top cover 23. Alternatively, it is contemplated that the vent plugs 42 may be slidingly engaged with the top cover so as to rotate within the casing 12 to obstruct part or all of the vent 30 openings. A third embodiment 44 is shown in FIG. 11. This embodiment shows a top cover 26 with no vent.

The invention conducts heat away from the notebook computer to lower the temperature of the notebook computer in one embodiment. In another embodiment, the device also uses convection through the use of an optional electric fan inside the device, allowing faster heat dissipation.

The operation of the second 40 and third 44 embodiments is similar to the first embodiment 10. The second embodiment 40 may have the vent plugs 42 in or out when in use. Alternatively, if the vent plugs were slidingly revealed, the level of closure may be adjusted by the user. The user would also operate the fan in the same fashion with a switch located on the side of the casing 12. It is understood that while the embodiments of the present invention have been discussed relative to portable computers, such as notebook and laptop computers, it is envisioned that other portable electronic devices would also work in connection with these embodiments. These include but are not limited to tablets, such as the Apple iPad® computing device, portable book tablets and other similar devices such as notebook, laptop, portable video players, portable books such as the Nook® tablet and the like.

It will be appreciated that the embodiments herein are described generally and that there a numerous alternative ways in which a number of features of the described embodiments may function. For example, with regard to the front or rear latch, one alternative embodiment may be a “pull down latch” where the latch would engage with an edge of the portable electronic device. Once the latch is fastened, the electronic device would be held securely to one of the embodiments described herein.

It will also be appreciated that the terms “upper,” “lower,” “front,” “rear,” “right,” and “left” are for the purposes of description only and are not intended to be limiting in any manner Similarly, as used herein, the singular forms “a,” “an,” and “the” include plural references unless the context clearly dictates otherwise. Thus, for example, the term “a computing device” or “a top cover” is intended to include both the singular and plural forms of these terms unless specifically stated otherwise.

1. A thermal management system for a portable computing device, the portable computing device having a lower surface, the system comprising:
a housing having an upper surface, a lower surface, and a space therebetween; and
a connector for releaseable engagement with the lower surface of a portable computing device.

2. The system of claim 1 further comprising an air movement system located between the lower and upper surface, the air movement system comprising a fan, and a power source to operate the fan, the power source in electrical communication with the fan.

3. The system of claim 2 wherein the power source comprises a battery located within the housing.

4. The system of claim 2 wherein the power comprises an electrical connector for electrically connecting to an external power source.

5. The system of claim 2 further comprising a controller for the power source.

6. The system of claim 1 wherein the housing includes an opening through which ambient air is drawn into the housing.

7. The system of claim 6 wherein the opening is between the upper and lower surface.

8. A portable computing device surface cooling system comprising:
a portable computing device having an upper surface and a lower surface; and
a cooling system having a base and a cover spaced apart from the base, the cooling system being removeably attached to the lower surface of the portable computing device, the cooling system cover adjacent to the lower surface of the portable computing device.

9. The system of claim 8 further comprising a fan assembly located between the cover and base, the fan assembly comprising a fan, and a power source, the power source in electrical communication with the fan.

10. The system of claim 9 wherein the power source comprises a battery located within the cooling system.

11. The system of claim 9 wherein the power source comprises an electrical connector for electrically connecting to an external power source.

12. The system of claim 9 further comprising a controller for the power source.

13. The system of claim 8 further comprising a vented opening in the cover.

14. The system of claim 13 wherein the size of the opening may be adjusted or closed.

15. The system of claim 1 further comprising an opening through which ambient air is drawn into the housing.

16. The system of claim 15 wherein the opening is located between the cover and the base.

17. A method of cooling the underside surface of a portable computer comprising the steps of:
providing a portable computer having a main body having an upper side and an underside;
removeably attaching a heat management assembly to the underside of the portable computer, the assembly having an upper surface, a lower surface and space therebetween, whereby the upper surface of the assembly is located proximate to the underside of the portable computer.

18. The method of claim 17 wherein the heat management assembly includes a fan system fixed within the space between the upper and lower surfaces.

19. The method of claim 18 wherein the fan system includes a power source and a controller for controlling the power source.

20. The method of claim 17 wherein the heat management assembly further comprises an opening through which ambient air is drawn into the housing.
